(19) United States
(12) Patent Application Publication
(10) Pub. No.: US 2010/0117163 A1
(43) Pub. Date: May 13, 2010

(54) SEMICONDUCTOR DEVICE AND METHOD OF FABRICATING THE SAME

(75) Inventor: Katsura Miyashita, Kanagawa (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/559,867

(22) Filed: Sep. 15, 2009

(30) Foreign Application Priority Data
Nov. 13, 2008 (JP) 2008-290730

(51) Int. Cl. H01L 29/78; H01L 21/336

(52) U.S. Cl. 257/408; 438/305; 257/E29.266; 257/E21.437

(57) ABSTRACT

A semiconductor device according to one embodiment includes: a gate electrode formed on a semiconductor substrate via a gate insulating film; first and second spacers respectively formed on two side faces of the gate electrode; a gate sidewall formed on a side face of the first spacer; a channel region formed in the semiconductor substrate under the gate insulating film; first and second impurity diffused layers respectively formed on the first spacer side and the second spacer side of the channel region, the first impurity diffused layer including a first extension region in the gate electrode side thereon, the second impurity diffused layer including a second extension region in the gate electrode side thereon; a first silicide layer formed on the first impurity diffused layer; and a second silicide layer formed on the second impurity diffused layer, the channel region being closer to the second silicide layer than the first silicide layer.

### CROSS-REFERENCE TO RELATED APPLICATIONS

This application is based upon and claims the benefit of priority from prior Japanese Patent Application No. 2008-290730, filed on Nov. 13, 2008, the entire contents of which are incorporated herein by reference.

### BACKGROUND

As a conventional semiconductor device, a transistor is known in which only an offset spacer (a narrow gate sidewall) is respectively formed on side faces of a gate electrode without forming a normal gate sidewall and a silicide layer is formed on an upper surface of each of source and drain regions. The semiconductor device, for example, is disclosed in non-patent literary document of A. Kinoshita et al., Extended Abstracts of the 2004 International Conference on Solid State Devices and Materials Tokyo, 2004, pp. 172-173.

According to this semiconductor device disclosed in the non-patent literary document, a silicide layer is formed in a region in the vicinity of an edge of an extension region of each of source and drain regions on a channel region side. Therefore, a conductivity type impurity in the extension region is pushed to the vicinity of an interface between the extension region and a semiconductor substrate by the silicide layer, and is thereby segregated. As a result, since an impurity profile in the extension region in the vicinity of the interface is highly concentrated as well as steep and interface parasitic resistance decreases, a transistor on-state current is improved. Note that, such technique is called a segregation Schottky technique, etc., and such structure is called a DSS (Dopant Segregated Schottky) structure, etc.

A semiconductor device with a DSS structure has high driving current characteristic because the semiconductor device has lower parasitic resistance and higher infusion rate of a carrier than a normal MOSFET. However, there is a problem that an off-state current is adversely affected because a distance from an interface between a silicide layer and a Si layer to a junction edge is extremely short in vicinity of a gate edge and a junction leak current thereby rises. On the other hand, a method of fabricating of a semiconductor device with an asymmetric sidewall spacer structure is known. The method, for example, is described in patent literary document of JP-A-2007-501518. According to this method disclosed in the patent literary document, the asymmetric sidewall spacer structure is formed by partially blocking ion beam using a photoresist structure. Therefore, there is a problem that a step for forming the photoresist structure must be added in a fabricating process for a semiconductor device.

### BRIEF SUMMARY

A semiconductor device according to one embodiment includes: a gate electrode formed on a semiconductor substrate via a gate insulating film; first and second spacers respectively formed on two side faces of the gate electrode;

a gate sidewall formed on a side face of the first spacer; a channel region formed in the semiconductor substrate under the gate insulating film; first and second impurity diffused layers respectively formed on the first spacer side and the second spacer side of the channel region, the first impurity diffused layer including a first extension region in the gate electrode side thereon, the second impurity diffused layer including a second extension region in the gate electrode side thereon; a first silicide layer formed on the first impurity diffused layer; and a second silicide layer formed on the second impurity diffused layer, the channel region being closer to the second silicide layer than the first silicide layer.

A method of fabricating a semiconductor device according to another embodiment includes: forming a gate electrode in a transistor region on a semiconductor substrate via a gate insulating film; respectively forming first and second spacers on two side faces of the gate electrode; forming extension regions of a source electrode and a drain electrode by implanting an impurity into the transistor regions on the semiconductor substrate using the first and second spacers and the gate electrode as a mask; respectively forming first and second gate sidewalls on side faces of the first and second spacers; selectively applying an anisotropic modification to the first gate sidewall; selectively removing the first gate sidewall after the anisotropic modification is applied to the first gate sidewall; and forming silicide layers on regions exposed in the transistor region of the semiconductor substrate after the first gate sidewall is removed.

A method of fabricating a semiconductor device according to another embodiment includes: forming a gate electrode in a transistor region on a semiconductor substrate via a gate insulating film; respectively forming first and second spacers on two side faces of the gate electrode; forming extension regions of a source electrode and a drain electrode by implanting an impurity into the transistor regions on the semiconductor substrate using the first and second spacers and the gate electrode as a mask; respectively forming first and second gate sidewalls on side faces of the first and second spacers; selectively applying an anisotropic modification to the second gate sidewall; selectively removing the first gate sidewall after the anisotropic modification is applied to the second gate sidewall; and forming silicide layers on regions exposed in the transistor region of the semiconductor substrate after the first gate sidewall is removed.

### BRIEF DESCRIPTION OF THE DRAWING

FIG. 1 is a cross sectional view of a semiconductor device according to a first embodiment;

FIGS. 2A to 2H are cross sectional views showing processes for fabricating the semiconductor device according to a second embodiment;

FIG. 3 is a cross sectional view showing a process corresponding to a modification process for a gate sidewall shown in FIG. 2D;

FIG. 4 is a cross sectional view of a conventional semiconductor device including a MOSFET; and

FIG. 5 is a cross sectional view of a conventional semiconductor device including a DSS MOSFET.

### DETAILED DESCRIPTION

### First Embodiment

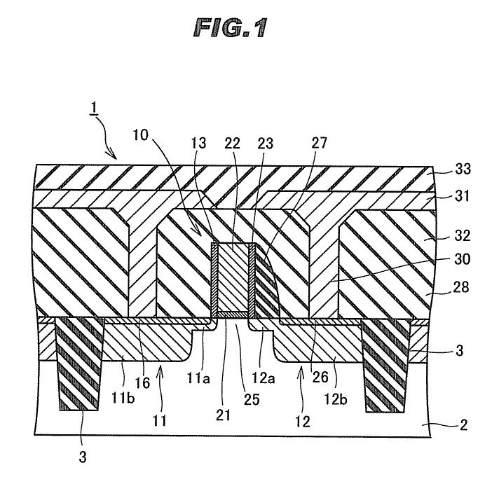

FIG. 1 is a cross sectional view of a semiconductor device 1 according to a first embodiment. The semiconductor device 1 includes an MOSFET 10 on a semiconductor substrate 2, and the MOSFET 10 is electrically isolated from peripheral elements by an element isolation region 3.

A bulk Si substrate, an SOT (Silicon on Insulator) substrate, etc., may be used for the semiconductor substrate 2.

The element isolation region 3 is made of, e.g., an insulating film such as SiO₂, etc., and has a STI (Shallow Trench Isolation) structure.

The MOSFET 10 is schematically configured to include a gate electrode 22 formed on the semiconductor substrate 2 via agate insulating film 21, offset spacers 13 and 23 respectively formed on side faces of the gate electrode 22, a gate sidewall formed on a side face of the offset spacer 23, a channel region 25 formed in the semiconductor substrate 2 under the gate insulating film 21, a source electrode 11 formed on the offset spacer 13 side of the channel region 25 in the semiconductor substrate 2, a drain electrode 12 formed on the offset spacer 23 side of the channel region 25 in the semiconductor substrate 2, and silicide layers 16 and 26 respectively formed on the source electrode 11 and drain electrode 12.

In addition, the semiconductor device 1 includes a wiring 31 contacted with the silicide layer 16 on the source electrode 11 and the silicide layer 26 on the drain electrode 12 via a via 30. Here, the via 30 is formed in an interlayer insulating film 32, and the wiring 31 is formed in a protective film 33.

The gate insulating film 21 is made of, e.g., SiO₂, SiN, SiON, or a high-dielectric material (e.g., an Hf-based material such as HfSiON, HfSiO or HfO, etc., a Zr-based material such as ZrSiON, ZrSiO or ZrO, etc., and a Y-based material such as Y₂O₃, etc.)

The gate electrode 22 is made of a Si-based polycrystalline such as polycrystalline Si or polycrystalline SiGe, etc., containing a conductivity type impurity. An n-type impurity such as As or P, etc., is used for the gate electrode 22 in case that the MOSFET 10 is an n-type MOSFET, and a p-type impurity such as B or BF₂, etc., is used for the gate electrode 22 in case that the MOSFET 10 is a p-type MOSFET. In addition, when the gate electrode 22 is made of a Si-based polycrystalline, a silicide layer may be formed on an upper portion thereof.

Alternatively, the gate electrode 22 may be a metal gate electrode made of W, Ta, Ti, Hf, Zr, Ru, Pt, Ir, Mo or Al, etc., or a compound thereof, etc. Furthermore, the gate electrode 22 may have a structure in which a metal gate electrode and a Si-based polycrystalline electrode are laminated.

The offset spacers 13 and 23 as a spacers are made of an insulating material such as SiO₂ or SiN, etc. Thicknesses of the offset spacers 13 and 23 affect formation positions of a extension region 11a of the source electrode 11, and a extension region 12a of the drain electrode 12 and the silicide layer 16, etc., and , for example, are preferably 12 nm.

The gate sidewall 27 is formed on only the side face of the offset spacer 23, and may have a single layer structure made of, e.g., SiN, a structure of two layer made of, e.g., SiN and SiO₂, or furthermore, a structure of three or more layers.

The source electrode 11 and drain electrode 12 are composed of an impurity diffused layer in which a conductivity type impurity is diffused. Here, in case that the MOSFET 10 is an n-type MOSFET, each of the source electrode 11 and drain electrode 12 is an n-type impurity diffused layer and an n-type impurity such as As or P, etc., is used as the conductivity type impurity. Moreover, in case that the MOSFET 10 is a p-type MOSFET, each of the source electrode 11 and drain electrode 12 is a p-type impurity diffused layer and a p-type impurity such as B or BF₂, etc., is used as the conductivity type impurity.

The source electrode 11 includes the shallow extension region 11a and a deep region 11b. The drain electrode 12 includes the shallow extension region 12a and a deep region 12b.

The silicide layers 16 and 26 are made of a metal such as Ni, Pt, Co, Er, Y, Yb, Ti, Pd, NiPt or CoNi, etc, with a compound containing Si, and are respectively formed on exposed portions of upper surfaces of the source electrode 11 and drain electrode 12. An edge of the silicide layer 16 contacts with the offset spacer 13 . In addition, an edge of the silicide layer 26 contacts with the gate sidewall 27. Therefore, the channel region 25 is closer to the silicide layer 16 than the silicide layer 26.

The silicide layer 16 is formed in a region in the vicinity of an edge of the extension region 11a on the channel region 25 side. This structure is characteristic of the DSS structure. Therefore, the conductivity impurity in the extension region 11a is pushed to the vicinity of an interface between the extension region 11a and the semiconductor substrate 2 by the silicide layer 16, and is segregated. As a result, since an impurity profile in the extension region 11a in the vicinity of the interface is highly concentrated as well as steep and interface parasitic resistance decreases, it is possible to improve an on-state current of the MOSFET 10. Note that, it is known that a level of improvement of an on-state current in an n-type MOSFET is larger than that in a p-type MOSFET.

On the other hand, the conductivity impurity in the extension region 12a is hardly segregated by forming the silicide layer 26 because the silicide layer 26 is formed so as to be separate from the edge of the extension region 12a on the channel region 25 side.

Note that, the MOSFET 10 may be MISFET (Metal Insulator Semiconductor Field Effect Transistor) in which a gate insulating film is not oxide.

### (Effect of the First Embodiment)

The semiconductor device 1 according to a first embodiment includes the MOSFET 10 with the asymmetric DSS structure in which only the conductivity impurity in the extension region ha of the source electrode 11 is segregated. Effects caused by this asymmetric DSS MOSFET are compared with that caused by a conventional MOSFET and a conventional DSS MOSFET shown below.

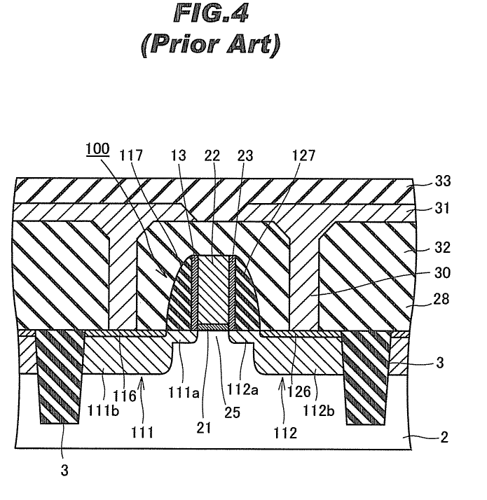

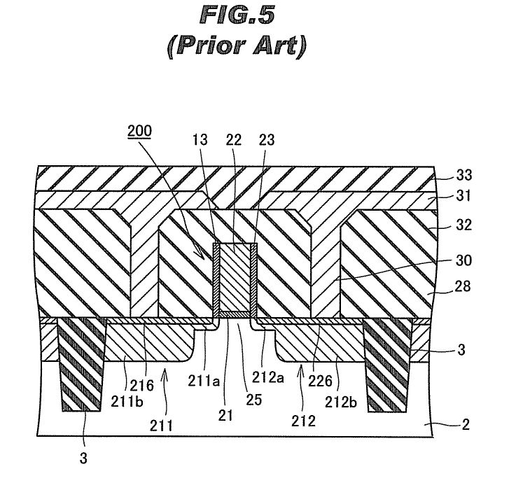

FIG. 4 is a cross sectional view of a conventional semiconductor device including a MOSFET 100. The MOSFET 100 has a structure in which gate sidewalls 117 and 127 are formed on both side of a gate electrode 22. Silicide layers 116 and 126 contact with the gate sidewalls 117 and 127, respectively. Therefore, a junction leak current is hardly generated because a distance from the silicide layers 126 to a drain junction is enough.

However, an electric resistance at a source edge is high and infusion rate of a carrier is low because a distance from the silicide layers 116 to a gate edge is large. Therefore, there is a problem that the conventional MOSFET structure is suitable for LSTP (Low Stand-by Power) CMOS, but is not suitable for HP (High Performance) CMOS much.

FIG. 5 is a cross sectional view of a conventional semiconductor device including a DSS MOSFET 200. The MOSFET 200 has a structure in which no gate sidewall is formed. Silicide layers 216 and 226 contact with offset spacers 13 and 23, respectively. Therefore, the DSS MOSFET 200 has high driving current characteristic because the DSS MOSFET 200 has lower parasitic resistance and higher infusion rate of a carrier than a normal MOSFET.

However, there is a problem that an off-state current is adversely affected because a distance from a silicide layer 216 to a source junction edge and a distance from a silicide layer 226 to a drain junction edge are extremely short in vicinity of a gate edge and a junction leak current thereby rises. For example, the conventional DDS technology is not suitable for LSTP CMOS in which an off-state current must be on the order of 1 pA/μm. Therefore, there is a problem that application of the DSS MOSFET is almost limited to application for HP (High Performance) product.

The semiconductor device 1 according to a first embodiment includes the MOSFET 10 has the asymmetric DSS structure in which the silicide layer 26 contacts with the gate sidewall 27. Therefore, a junction leak current is hardly generated because a distance from the silicide layers 26 to a drain junction is enough. On the other hand, the semiconductor device 1 has no gate side wall on the source electrode 11 side, and the silicide layer 16 contacts with the offset spacer 13. Therefore, the semiconductor device 1 has high driving current characteristic because the semiconductor device 1 has lower parasitic resistance and higher infusion rate of a carrier than a normal MOSFET.

Thus, problems of a conventional MOSFET and a conventional DSS MOSFET are overcome, and only advantages of them are utilized in the semiconductor device 1 with the asymmetric DSS structure. In fact, an electric resistance at a source edge is low enough because the semiconductor device 1 has the DSS structure on the source electrode 11 side. In addition, a junction leak current is hardly generated because a distance from the silicide layers 26 to a drain junction is enough. Therefore, the asymmetric DSS structure can be applied not only to HP CMOS, but also to LSTP.

### Second Embodiment

FIGS . 2A to 2H are cross sectional views showing processes for fabricating the semiconductor device 1 according to a second embodiment.

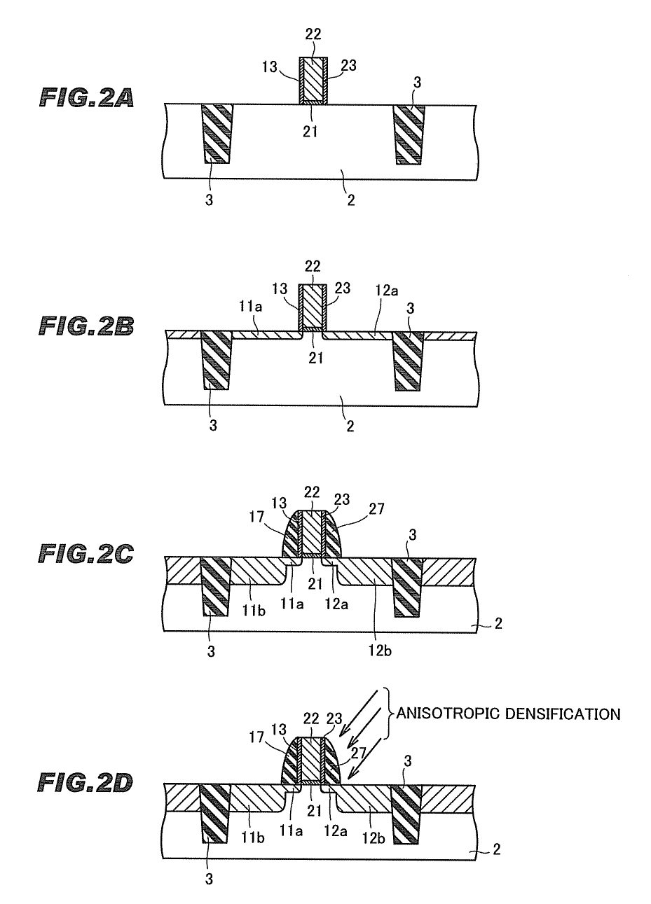

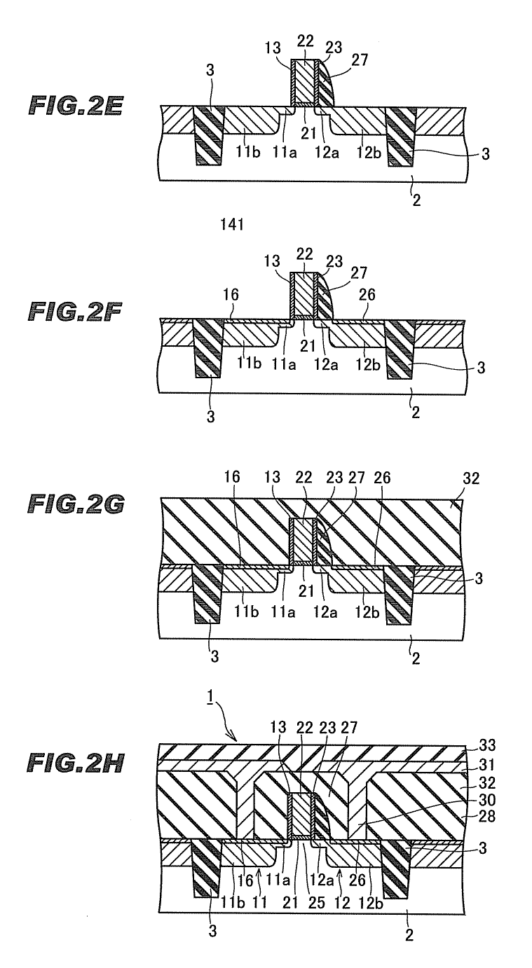

Firstly, as shown in FIG. 2A, after a transistor region for forming the MOSFET 10 is laid out by forming the element isolation region 3 on the semiconductor substrate 2, the gate insulating film 21, the gate electrode 22 and the offset spacers 13 and 23 are formed on the semiconductor substrate 2.

Next, as shown in FIG. 2B, a conductivity type impurity is implanted into the semiconductor substrate 2 by an ion implantation procedure using the gate electrode 22 and the offset spacers 13 and 23 as a mask, thereby forming the extension regions 11a and 12b in the transistor region. Here, an n-type impurity such as As or P, etc., is implanted in case that the MOSFET 10 is an n-type MOSFET, and a p-type impurity such as B, BF₂ or In, etc., is implanted in case that the MOSFET 10 is a p-type MOSFET.

Next, as shown in FIG. 2C, after respectively forming gate sidewalls 17 and 27 on the side faces of the offset spacers 13 and 23, a conductive type impurity is implanted into the semiconductor substrate 2 by an ion implantation procedure using the gate sidewalls 17 and 27 as a mask, thereby forming the deep regions 11b and 12b in the transistor region.

Here, for example, after depositing a material film of the gate sidewalls 17 and 27 such as SiO₂, etc., so as to cover the side faces of the offset spacers 13 and 23, the material film is etched by RIE (Reactive Ion Etching) method, which results in that the gate sidewalls 17 and 27 are formed. In addition, the deep regions 11b and 12b are formed by implanting an n-type impurity such as As or P, etc., into the transistor region in case that the MOSFET 10 is an n-type MOSFET or by implanting a p-type impurity such as B, BF₂ or In, etc., into the transistor region in case that the MOSFET 10 is a p-type MOSFET.

Next, as shown in FIG. 2D, an anisotropic modification such as anisotropic densification is applied to the gate sidewall 27. For example, ion implantation, plasma doping, laser irradiation or local annealing is used as the anisotropic densification. For example, the gate sidewall 27 is locally heated at high temperature by laser irradiation or local annealing, and the density of the gate sidewall 27 can be thereby increased.

The anisotropic densification such as laser irradiation is applied at a predetermined angle using the offset spacers 13 and 23 as masks. As a result, densification is applied to the gate sidewall 27, which is a gate sidewall located on the drain electrode 12 side, but not applied to the gate sidewall 17, which is a gate sidewall located on the source electrode 11 side. The gate sidewall 27 is compressed and densified by the anisotropic densification, while the gate sidewall 17 is not modified.

Next, as shown in FIG. 2E, only the gate sidewall 17 is removed by etching. The gate sidewalls 17 and 27 are etched using hot phosphoric acid when these are made of SiN. On the other hand, the gate sidewalls 17 and 27 are etched using hydrofluoric acid when these are made of SiO₂. In this etching treatment, only the gate sidewall 17 is removed because etching rate of the gate sidewall 27 to which the densification is applied is lower than that of the gate sidewall 17. Note that, it is preferable that the gate sidewall 17 and the offset spacer 13 have a certain level of etching selectivity in order to leave the offset spacer 13 without being removed.

Next, as shown in FIG. 2F, the silicide layers 16 and 26 are formed by the public self-align silicide process. A metal film made of Ni, etc., is deposited by sputtering so as to cover the exposed portions of the upper surfaces of the source electrode 11 and drain electrode 12, and silicidation reaction is generated on an interface between the metal film and the source electrode 11 and an interface between the metal film and the drain electrode 12 by RTA at 400-500° C., which results in that the silicide layers 16 and 26 are formed. And then, an unreacted portion of the metal film is removed by etching with a mixed solution of sulfuric acid and hydrogen peroxide solution.

At this time, since a region in the upper surface of the source electrode 11, which is not covered by the offset spacer 13, is exposed, the silicide layer 16 is formed so that the edge thereof contacts with the offset spacer 13. Meanwhile, since a region in the upper surface of the drain electrode 12, which is not covered by the offset spacer 23 and the gate sidewall 27, is exposed, the silicide layer 26 is formed so that the edge thereof contacts with the gate sidewall 27. In other words, the silicide layer 26 is formed so that the edge thereof separates from the offset spacer 23.

Next, as shown in FIG. 2G, the interlayer insulating film 32 is formed on the whole surface of the semiconductor substrate 2 by the plasma CVD method, etc.

Next, as shown in FIG. 2H, the semiconductor device 1 shown in FIG. 1 is obtained by forming the protective film 33 after forming the via 30 and wiring 31.

### (Effect of the Second Embodiment)

According to the method of fabricating of a semiconductor device in the second embodiment, it becomes possible to fabricate the MOSFET 10 with the asymmetric DSS structure shown in the first embodiment without using high cost process such as photoresist process because the gate sidewall 17 is removed by the anisotropic densification. Therefore, it becomes possible to fabricate a MOSFET or CMOS having HP (high performance) and LSTP (Low Stand-by Power).

Note that, the MOSFET 10 may be NISFET (Metal Insulator Semiconductor Field Effect Transistor) in which a gate insulating film is not oxide.

### Third Embodiment

A method of fabricating of a semiconductor device according to the third embodiment is different from that according to the second embodiment in a method of removing the gate sidewall 17.

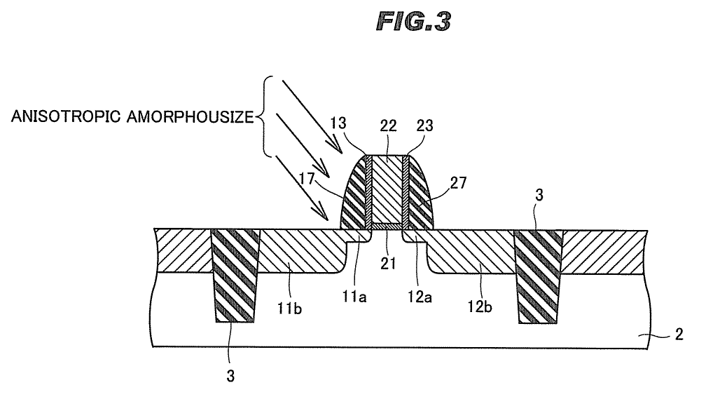

FIG. 3 is a cross sectional view showing a process corresponding to a modification process for a gate sidewall, which is shown in FIG. 2D, described in the second embodiment.

Although an anisotropic modification such as the anisotropic densification is applied to the gate sidewall 27 located on the drain electrode 12 side in order to selectively remove the gate sidewall 17 located on the source electrode 11 side in the second embodiment, a modification such as an anisotropic amorphousize is applied to the gate sidewall 17 located on the source electrode 11 side in the third embodiment.

As shown in FIG. 3, the gate sidewall 17 can be modified to low density membrane and is amorphized by, for example, laser radiation and subsequent rapid cooling. The laser radiation is applied at a predetermined angle using the offset spacers 13 and 23 as masks. As a result, the gate sidewall 17 located on the source electrode 11 side is modified, while the gate sidewall 27 located on the drain electrode 12 side is not modified. In addition, the gate sidewall 17 may be amorphized by implanting Ge ions with concentration of approximately 1×10¹⁴-1×10¹⁶ cm⁻² to the gate sidewall 17 by ion implantation or plasma doping in order to break a crystalline texture thereof.

After above-mentioned processes, only the gate sidewall 17 is removed by etching. The gate sidewalls 17 and 27 are etched using hot phosphoric acid when these are made of SiN. On the other hand, the gate sidewalls 17 and 27 are etched using hydrofluoric acid when these are made of SiO₂. In this etching treatment, only the gate sidewall 17 is removed because etching rate of the gate sidewall 17 to which the amorphousize is applied is higher than that of the gate sidewall 27. Note that, it is preferable that the gate sidewall 17 and the offset spacer 13 have a certain level of etching selectivity in order to leave the offset spacer 13 without being removed.

Since the other processes are the same as those in the second embodiment, the descriptions thereof are omitted here for the sake of simplicity.

### (Effect of the Third Embodiment)

According to the method of fabricating of a semiconductor device in the third embodiment, it becomes possible to fabricate the MOSFET 10 with the asymmetric DSS structure shown in the first embodiment without using high cost process such as photoresist process because the gate sidewall 17 is removed by the anisotropic amorphousize. Therefore, it becomes possible to fabricate a MOSFET or CMOS having HP (high performance) and LSTP (Low Stand-by Power)

Note that, the MOSFET 10 may be MISFET (Metal Insulator Semiconductor Field Effect Transistor) in which a gate insulating film is not oxide.

### Other Embodiments

It should be noted that the present invention is not intended to be limited to the above-mentioned first to third embodiments, and the various kinds of changes thereof can be implemented by those skilled in the art without departing from the gist of the invention.

In addition, the constituent elements of the above-mentioned embodiments can be arbitrarily combined with each other without departing from the gist of the invention.

What is claimed is:

1. A semiconductor device, comprising:
a gate electrode formed on a semiconductor substrate via a gate insulating film;
first and second spacers respectively formed on two side faces of the gate electrode;
a gate sidewall formed on a side face of the first spacer;
a channel region formed in the semiconductor substrate under the gate insulating film;
first and second impurity diffused layers respectively formed on the first spacer side and the second spacer side of the channel region, the first impurity diffused layer including a first extension region in the gate electrode side thereon, the second impurity diffused layer including a second extension region in the gate electrode side thereon;
a first silicide layer formed on the first impurity diffused layer; and
a second silicide layer formed on the second impurity diffused layer, the channel region being closer to the second silicide layer than the first silicide layer.

2. The semiconductor device according to claim 1, wherein the first and second impurity diffused layers function as drain electrode and source electrode, respectively.

3. The semiconductor device according to claim 2, wherein a conductivity impurity in the second extension region is segregated in the vicinity of an interface between the second extension region and the semiconductor substrate.

4. The semiconductor device according to claim 3, wherein the first silicide layer contacts with the gate sidewall; and
the second silicide layer contacts with the second spacer.

5. The semiconductor device according to claim 4, wherein each of the first and second impurity diffused layers is an n-type impurity diffused layer.

6. The semiconductor device according to claim 2, wherein the first silicide layer contacts with the gate sidewall; and
the second silicide layer contacts with the second spacer.

7. The semiconductor device according to claim 2, wherein each of the first and second impurity diffused layers is an n-type impurity diffused layer.

8. The semiconductor device according to claim 1, wherein a conductivity impurity in the second extension region is segregated in the vicinity of an interface between the second extension region and the semiconductor substrate.

9. The semiconductor device according to claim 8, wherein the first silicide layer contacts with the gate sidewall; and
the second silicide layer contacts with the second spacer.

10. The semiconductor device according to claim 9, wherein each of the first and second impurity diffused layers is an n-type impurity diffused layer.

11. The semiconductor device according to claim 1, wherein the first silicide layer contacts with the gate sidewall; and
the second silicide layer contacts with the second spacer.

12. The semiconductor device according to claim 1, wherein each of the first and second impurity diffused layers is an n-type impurity diffused layer.

13. A method of fabricating a semiconductor device, comprising:
forming a gate electrode in a transistor region on a semiconductor substrate via a gate insulating film;
respectively forming first and second spacers on two side faces of the gate electrode;
forming extension regions of a source electrode and a drain electrode by implanting an impurity into the transistor regions on the semiconductor substrate using the first and second spacers and the gate electrode as a mask;
respectively forming first and second gate sidewalls on side faces of the first and second spacers;
selectively applying an anisotropic modification to the first gate sidewall;
selectively removing the first gate sidewall after the anisotropic modification is applied to the first gate sidewall; and
forming silicide layers on regions exposed in the transistor region of the semiconductor substrate after the first gate sidewall is removed.

14. The method of fabricating a semiconductor device according to claim. 13, wherein the anisotropic modification is a densification using at least one of ion implantation, plasma doping, laser irradiation, and local annealing.

15. The method of fabricating a semiconductor device according to claim 14, wherein the extension region of the source electrode is formed on the first spacer side; and
the extension region of the drain electrode is formed on the second spacer side.

16. The method of fabricating a semiconductor device according to claim 13, wherein the extension region of the source electrode is formed on the first spacer side; and
the extension region of the drain electrode is formed on the second spacer side.

17. A method of fabricating a semiconductor device, comprising:
forming a gate electrode in a transistor region on a semiconductor substrate via a gate insulating film;
respectively forming first and second spacers on two side faces of the gate electrode;
forming extension regions of a source electrode and a drain electrode by implanting an impurity into the transistor regions on the semiconductor substrate using the first and second spacers and the gate electrode as a mask;
respectively forming first and second gate sidewalls on side faces of the first and second spacers;
selectively applying an anisotropic modification to the second gate sidewall;
selectively removing the first gate sidewall after the anisotropic modification is applied to the second gate sidewall; and
forming suicide layers on regions exposed in the transistor region of the semiconductor substrate after the first gate sidewall is removed.

18. The method of fabricating a semiconductor device according to claim. 17, wherein the anisotropic modification is an amorphousize using at least one of ion implantation, plasma doping and laser irradiation.

19. The method of fabricating a semiconductor device according to claim 18, wherein the extension region of the source electrode is formed on the first spacer side; and
the extension region of the drain electrode is formed on the second spacer side.

20. The method of fabricating a semiconductor device according to claim 17, wherein the extension region of the source electrode is formed on the first spacer side; and
the extension region of the drain electrode is formed on the second spacer side.
